(19) United States
(12) Patent Application Publication
(10) Pub. No.: US 2022/0073814 A1
(43) Pub. Date: Mar. 10, 2022

(54) COMPOSITION

(71) Applicant: Merck Patent GmbH, Darmstadt (DE)

(72) Inventor: Itai LIEBERMAN, Dreieich (DE)

(73) Assignee: Merck Patent GmbH, Darmstadt (DE)

(21) Appl. No.: 17/415,779

(22) PCT Filed: Dec. 17, 2019
(86) PCT No.: PCT/EP2019/085534

§ 371 Date: Jun. 18, 2021

(30) Foreign Application Priority Data
Dec. 20, 2018 (EP) 18214774.4

(51) Int. Cl. C09K 11/02; C09K 11/70; C09K 11/08; H01L 51/00; H01L 51/50

(52) U.S. Cl. CPC C09K 11/025; C09K 11/70; B82Y 30/00; H01L 51/005; H01L 51/5008; C09K 11/0883

(57) ABSTRACT

The present invention relates to a composition comprising a nanoparticle and a process for preparation thereof.

### FIELD OF THE INVENTION

The present invention relates to a composition comprising a semiconducting light emitting nanoparticle, a process for preparing a composition, use of a composition, use of a chemical compound, an optical medium, and an optical device.

### BACKGROUND ART

U.S. Pat. No. 9,701,896 B1 discloses a composition including quantum dots and emission stabilizer of TOPO, TOPO+KDP, or TOPO+Zn oleate.

US 2010/068522 A1 discloses an InP quantum dots functionalized with 10-Undecylenic acids.

APL Materials 4, 040702 (2016) mentions addition of trioctylphosphine oxide to an acrylic polymer composition prior to curing of the composition.

CN 106590629 A discloses improved stability of perovskite quantum dots by crystalizing carboxy benzene around the quantum materials.

### PATENT LITERATURE

1. U.S. Pat. No. 9,701,896 B1
2. US 2010/068522 A1
3. CN 106590629 A

### NON-PATENT LITERATURE

4. APL Materials 4, 040702 (2016)

### SUMMARY OF THE INVENTION

However, the inventors newly have found that there is still one or more of considerable problems for which improvement is desired, as listed below; improvement of quantum yield of nanoparticle, preventing or reducing a quantum yield drop under in a diluted composition and/or in a radical rich environment, higher device efficiency, optimizing a surface condition of shell part of nanoparticle, reducing lattice defects of a shell layer of nanoparticle, reducing/preventing formation of dangling bonds of shell layer, better thermal stability, improved oxidation stability, improved stability to a radical substances, improved stability during a long term storage without causing a significant QY drop, better chemical stability, environmentally more friendly and safer fabrication process.

The inventors aimed to solve one or more of the above-mentioned problems.

Then it was found a novel process for preparing of a composition comprising, essentially consisting of, consisting of, following steps;

a) mixing at least a 1^{st} organic compound with a semiconducting light emitting nanoparticle comprising a core, optionally the nanoparticle comprises at least one shell layer, to get a 1^{st} mixture, preferably with another material,
wherein said 1^{st} organic compound is represented by following chemical formula (I),

A(B)ₙC (I)

where A represents a first end group; B is a divalent bond; C is a second end group; n is 0 or 1.

In another aspect, the present invention also relates to a composition obtainable or obtained by the process of the present invention.

In another aspect, the present invention further relates to a composition comprising, essentially consisting of, consisting of, at least

a) one semiconducting light emitting nanoparticle comprising a core, optionally at least one shell layer,
b) a 1^{st} chemical compound, and
c) optionally another compound,
wherein said 1^{st} organic compound is represented by following chemical formula (I),

A(B)ₙC (I)

where A represents a first end group; B is a divalent bond; C is a second end group; n is 0 or 1.

In another aspect, the present invention also relates to use of the 1^{st} chemical compound represented by chemical formula I) in a composition comprising at least one semiconducting light emitting nanoparticle, or a process for making composition, or a process for making an optical device,

A(B)ₙC (I)

where A represents a first end group; B is a divalent bond; C is a second end group; n is 0 or 1.

In another aspect, the present invention also relates to use of the composition of the present invention, in an electronic device, optical device or in a biomedical device.

In another aspect, the present invention further relates to an optical medium comprising at least one semiconducting light emitting nanoparticle, and a 1^{st} chemical compound represented by chemical formula I)

A(B)ₙC (I)

where A represents a first end group; B is a divalent bond; C is a second end group; n is 0 or 1.

In another aspect, the present invention further relates to an optical device comprising at least one optical medium of the present invention.

### DESCRIPTION OF DRAWINGS

FIG. 1 shows the QY measurement results of comparative example 1.

FIG. 2 shows the QY measurement results of working example 1.

FIG. 3 shows the QY measurement results of working example 2.

FIG. 4 shows the results of the QY measurements of 7 different samples of comparative example 2.

FIG. 5 shows the results of the QY measurements of working example 3.

FIG. 6 shows the results of the QY measurements of working example 4.

FIG. 7 shows the results of the QY measurements of working example 5.

### DETAILED DESCRIPTION OF THE INVENTION

According to the present invention the process for preparing of a composition comprises, essentially consisting of, or consisting of, following steps;

a) mixing at least a 1^{st} organic compound with a semiconducting light emitting nanoparticle comprising a core, optionally the nanoparticle comprises at least one shell layer, to get a 1^{st} mixture, preferably with another material, preferably said 1^{st} mixture is a composition,
wherein said 1^{st} organic compound is represented by following chemical formula (I),

A(B)ₙC (I)

where A represents a first end group; B is a divalent bond; C is a second end group; n is 0 or 1.

1^{st} Organic Compound

As described above, the 1^{st} organic compound is represented by following chemical formula (I),

A(B)ₙC (I)

where A represents a first end group; B is a divalent bond; C is a second end group; n is 0 or 1.

One or more of publicly available chemical compounds represented by above mentioned formula (I) or below mentioned chemical formula (II) are preferably selected, e.g. thiols, carboxylic acids, phosphonic acids, and/or mercaptoacetates.

And ligand materials represented by chemical formula (I) or (II) described in for example, the laid-open international patent application No. WO 2012/059931A can also be used.

In a preferred embodiment of the present invention, the amount of the 1^{st} organic compound in the composition is in the range from 0.01 wt. % to 100 wt. % based on the total amount of the inorganic part of the semiconducting light emitting nanoparticle in the composition, preferably it is in the range from 10 wt. % to 50 wt. %, more preferably from 20 wt. % to 30 wt. %.

In a preferred embodiment of the present invention, the 1^{st} organic compound is represented by following chemical formula (II);

XR¹R²(R³)ₙ (II)

wherein X is selected from P, O, S, or N;
n is 0 in case X is O or S, n is 1 in case X is P or N;

R¹ is selected from one or more members of the group consisting of a hydrogen atom, a linear alkyl group or alkoxyl group having 1 to 40 carbon atoms, preferably 1 to 25 carbon atoms, more preferably 1 to 15 carbon atoms, a branched alkyl group or alkoxyl group having 3 to 40 carbon atoms, preferably 3 to 25 carbon atoms, more preferably 3 to 15 carbon atoms, a cycloalkane group having 3 to 40 carbon atoms, preferably 3 to 25 carbon atoms, more preferably 3 to 15 carbon atoms, an alkenyl group having 2 to 40 carbon atoms, preferably 2 to 25 carbon atoms, an aryl group having 3 to 40 carbon atoms, preferably 3 to 25 carbon atoms, a hetero aryl group having 3 to 40 carbon atoms, preferably 3 to 25 carbon atoms, and an aralkyl group having 4 to 40 carbon atoms, preferably 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, Cl, Br, I, CN or NO₂, or an aromatic or heteroaromatic ring system having 5 to 60 aromatic ring atoms, which may be substituted by one or more radicals R^{a};

R^{a} is at each occurrence, identically or differently, H, D, or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

R² is selected from one or more members of the group consisting of a hydrogen atom, a linear alkyl group or alkoxyl group having 1 to 40 carbon atoms, preferably 1 to 25 carbon atoms, more preferably 1 to 15 carbon atoms, a branched alkyl group or alkoxyl group having 3 to 40 carbon atoms, preferably 3 to 25 carbon atoms, more preferably 3 to 15 carbon atoms, a cycloalkane group having 3 to 40 carbon atoms, preferably 3 to 25 carbon atoms, more preferably 3 to 15 carbon atoms, an alkenyl group having 2 to 40 carbon atoms, preferably 2 to 25 carbon atoms, an aryl group having 3 to 40 carbon atoms, preferably 3 to 25 carbon atoms, a hetero aryl group having 3 to 40 carbon atoms, preferably 3 to 25 carbon atoms, and an aralkyl group having 4 to 40 carbon atoms, preferably 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, Cl, Br, I, CN or NO₂, or an aromatic or heteroaromatic ring system having 5 to 60 aromatic ring atoms, which may be substituted by one or more radicals R^{a};

R³ is selected from one or more members of the group consisting of a hydrogen atom, a linear alkyl group or alkoxyl group having 1 to 40 carbon atoms, preferably 1 to 25 carbon atoms, more preferably 1 to 15 carbon atoms, a branched alkyl group or alkoxyl group having 3 to 40 carbon atoms, preferably 3 to 25 carbon atoms, more preferably 3 to 15 carbon atoms, a cycloalkane group having 3 to 40 carbon atoms, preferably 3 to 25 carbon atoms, more preferably 3 to 15 carbon atoms, an alkenyl group having 2 to 40 carbon atoms, preferably 2 to 25 carbon atoms, an aryl group having 3 to 40 carbon atoms, preferably 3 to 25 carbon atoms, a hetero aryl group having 3 to 40 carbon atoms, preferably 3 to 25 carbon atoms, and an aralkyl group having 4 to 40 carbon atoms, preferably 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, Cl, Br, I, CN or NO₂, or an aromatic or heteroaromatic ring system having 5 to 60 aromatic ring atoms, which may be substituted by one or more radicals R^{a};

wherein at least one of R¹, R², R³ is not a hydrogen atom.

In a preferred embodiments of the present invention, the 1^{st} organic compound is selected from the group consisting of thiols, selenols, phosphonic acids, carboxylic acids, amines, and phosphines, preferably it is a thiol, carboxylic acid, or a phosphonic acid, such as hexane-1-thiol, carboxylic acids, 1-dodecanethiol, or hexylphosphonic acid, even more preferably it is a thiol.

Preferably, R² of the formula II) is a substituted or non-substituted linear alkyl group or alkoxyl group having 1 to 40 carbon atoms, preferably 3 to 25 carbon atoms, more preferably 5 to 15 carbon atoms; a substituted or non-substituted branched alkyl group or alkoxyl group having 3 to 40 carbon atoms, preferably 3 to 25 carbon atoms, more preferably 5 to 20 carbon atoms; a substituted or non-substituted cycloalkane group having 3 to 40 carbon atoms, preferably 3 to 25 carbon atoms, more preferably 5 to 25 carbon atoms; a substituted or non-substituted aryl group having 3 to 40 carbon atoms, preferably 5 to 25 carbon atoms.

More preferably, R² is a substituted linear alkyl group having 1 to 40 carbon atoms, a non-substituted branched alkyl group or alkoxyl group having 3 to 40 carbon atoms, preferably 3 to 25 carbon atoms, more preferably 5 to 25 carbon atoms.

More preferably, R² is selected from the group of following table 1. Table 1

TABLE 1

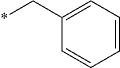

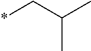

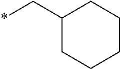

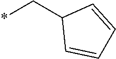

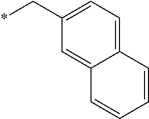

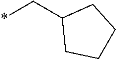

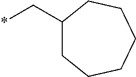

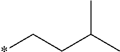

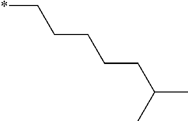

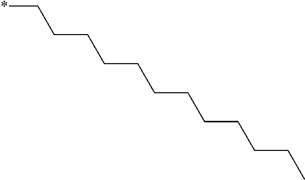

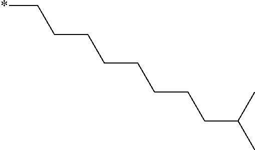

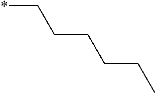

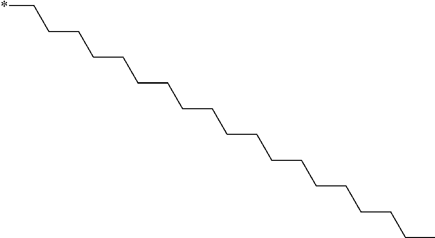

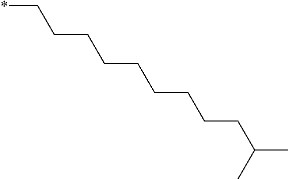

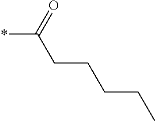

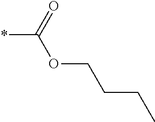

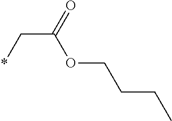

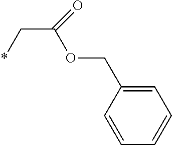

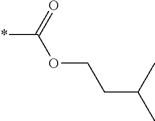

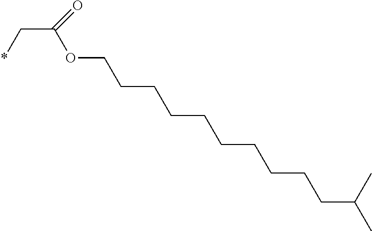

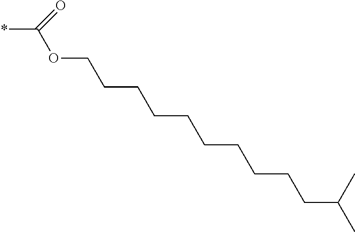

wherein and “*” represents the connecting point to another unit.

As the chemical compound, publicly available mercaptoacetates and/or mercaptopropionates are furthermore suitable as the chemical compound to prevent/reduce Quantum Yield drop of the semiconducting light emitting nanoparticle in a mixture, preferable in a solution, especially in the presence of a photo-initiators.

Publicly available following chemical compounds are especially suitable.

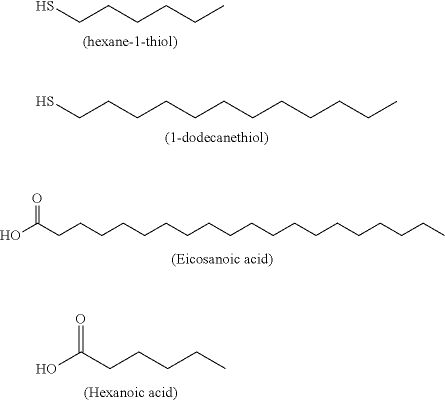

According to the present invention, preferably step a) is carried out with said another material, and the amount of the another material is in the range from 0.01 wt. % to 100 wt. % based on the total amount of the inorganic part of the semiconducting light emitting nanoparticle, preferably it is in the range from 0.1 wt. % to 50 wt. %, more preferably from 20 wt. % to 30 wt. %.

In some embodiments of the present invention, wherein step a) is carried out with said another material, and said another material is selected from one or more members of the group consisting of photo initiators, thermo initiators, inorganic materials, organic compounds, and solvents.

In some embodiments of the present invention, said another compound is a solvent selected from inorganic solvents, organic solvents, and a mixture of these, preferably it is selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, and dichlorobenzene, preferably said solvent is propylene glycol alkyl ether acetates, alkyl acetates, ethylene glycol monoalkyl ethers, propylene glycol, and propylene glycol monoalkyl ethers; preferably the solvent is selected from one or more members of the group consisting of propylene glycol alkyl ether acetates, such as, propylene glycol monomethyl ether acetate (PGMEA), alkyl acetates such as butyl acetate, ethylene glycol monoalkyl ethers such as ethylene glycol monobutyl ether, propylene glycol or propylene glycol monoalkyl ethers such as methoxypropanol, more preferably the solvent is selected from propylene glycol alkyl ether acetates.

In some embodiments of the present invention, said another compound is selected from photo-initiators, thermos-initiators or a mixture of these.

Semiconducting Light Emitting Nanoparticle

According to the present invention, the term “semiconductor” means a material that has electrical conductivity to a degree between that of a conductor (such as copper) and that of an insulator (such as glass) at room temperature. Preferably, a semiconductor is a material whose electrical conductivity increases with the temperature.

The term “nano” means the size in between 0.1 nm and 999 nm, preferably 1 nm to 150 nm, more preferably 3 nm to 50 nm.

Thus, according to the present invention, “semiconducting light emitting nanoparticle” is taken to mean that the light emitting material which size is in between 0.1 nm and 999 nm, preferably 1 nm to 150 nm, more preferably 3 nm to 50 nm, having electrical conductivity to a degree between that of a conductor (such as copper) and that of an insulator (such as glass) at room temperature, preferably, a semiconductor is a material whose electrical conductivity increases with the temperature, and the size is in between 0.1 nm and 999 nm, preferably 0.5 nm to 150 nm, more preferably 1 nm to 50 nm.

According to the present invention, the term “size” means the average diameter of the longest axis of the semiconducting nanosized light emitting particles.

The average diameter of the semiconducting nanosized light emitting particles is calculated based on 100 semiconducting light emitting nanoparticles in a TEM image created by a Tecnai G2 Spirit Twin T-12 Transmission Electron Microscope.

In a preferred embodiment of the present invention, the semiconducting light emitting nanoparticle of the present invention is a quantum sized material. Such as a quantum dot.

According the present invention, the shape of the quantum dot is not particularly limited. For examples, spherical shaped, elongated shaped, star shaped, polyhedron shaped, pyramidal shaped, tetrapod shaped, tetrahedron shaped, platelet shaped, cone shaped, and irregular shaped quantum dots can be used.

According to the present invention, the term “quantum sized” means the size of the semiconducting material itself without ligands or another surface modification, which can show the quantum confinement effect, like described in, for example, ISBN:978-3-662-44822-9.

In a preferred embodiment of the present invention, the nanoparticle comprising at least

i) the first semiconducting material;
ii) optionally at least one shell layer;
iii) optionally a chemical compound as a surface ligand attached onto the outermost surface of the nanoparticle such as the outermost surface of the first semiconducting material or the shell layer;
in this sequence.

For example, publicly available quantum dots, such as CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS, InZnPS/ZnS, InZnPS ZnSe, InZnPS/ZnSe/ZnS, ZnSe/CdS, ZnSe/ZnS or combination of any of these, can be used. Preferably, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS can be used.

CdS, CdSe, CdTe, ZnS, ZnSe, ZnSeS, ZnTe, ZnO, GaAs, GaP, GaSb, HgS, HgSe, HgSe, HgTe, InAs, InP, InPS, InPZnS, InPZn, InPZnSe, InCdP, InPCdS, InPCdSe, InGaP, InGaPZn, InSb, AlAs, AlP, AlSb, Cu₂S, Cu₂Se, CuInS₂, CuInSe₂, Cu₂(ZnSn)S₄, Cu₂(InGa)S₄, TiO₂ alloys and a combination of any of these can be used as the first semiconducting material (core).

In a preferred embodiment of the present invention, the first semiconducting material comprises at least one element of group 13 elements or 12 elements of the periodic table and one element of group 16 elements of the periodic table, preferably said element of group 13 elements is selected from In, Ga, Al, Ti, said element of group 12 is Zn or Cd, and said element of group 15 elements is selected from P, As, Sb, more preferably said first semiconducting material is represented by following chemical formula (III),

In_{(1-x-2/3y)}GaₓZn_{y}P (III)

wherein 0≤x<1, 0≤y<1, 0≤x+y<1, preferably said first semiconducting material is selected from the group consisting of InP, InP:Zn, InP:ZnS, InP:ZnSe, InP:ZnSSe, InP:Ga.

According to the present invention, a type of shape of the first semiconducting material of the semiconducting light emitting nanoparticle, and shape of the semiconducting light emitting nanoparticle to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped first semiconducting material and—or a semiconducting light emitting nanoparticle can be synthesized.

In some embodiments of the present invention, the average diameter of the first semiconducting materials in the range from 1.5 nm to 3.5 nm.

In some embodiments of the present invention, said semiconducting light emitting nanoparticle comprises at least one the shell layer comprises or a consisting of a 1^{st} element of group 12 of the periodic table and a 2^{nd} element of group 16 of the periodic table, preferably, the 1^{st} element is Zn, and the 2^{nd} element is S, Se, or Te.

In a preferred embodiment of the present invention, the shell layer is represented by following formula (IV),

ZnSₓSe_{(1-x-z)}Te_{z}, (IV)

wherein 0≤x≤1, 0≤z≤1, and x+z≤1, preferably, the shell layer is ZnSe, ZnSₓSe₍₁₋ₓ₎, ZnSe₍₁₋ₓ₎Te_{z}, ZnS, Zn, more preferably it is ZnSe or ZnS.

In some embodiments of the present invention, said shell layer is an alloyed shell layer or a graded shell layer, preferably said graded shell layer is ZnSₓSe_{y}, ZnSe_{y}Te_{z}, or ZnSₓTe_{z}, more preferably it is ZnSₓSe_{y}.

In some embodiments of the present invention, the semiconducting light emitting nanoparticle further comprises 2^{nd} shell layer onto said shell layer, preferably the 2^{nd} shell layer comprises or a consisting of a 3^{rd} element of group 12 of the periodic table and a 4^{th} element of group 16 of the periodic table, more preferably the 3^{rd} element is Zn, and the 4^{th} element is S, Se, or Te with the proviso that the 4^{th} element and the 2^{nd} element are not same.

In a preferred embodiment of the present invention, the 2^{nd} shell layer is represented by following formula (IV′),

ZnSₓSe_{y}Te_{z}, (IV′)

wherein the formula (IV′), 0≤x≤1, 0≤y≤1, 0≤z≤1, and x+y+z=1, preferably, the shell layer is ZnSe, ZnSₓSe_{y}, ZnSe_{y}Te_{z}, or ZnSₓTe_{z} with the proviso that the shell layer and the 2^{nd} shell layer is not the same.

In some embodiments of the present invention, said 2^{nd} shell layer can be an alloyed shell layer.

In some embodiments of the present invention, the semiconducting light emitting nanoparticle can further comprise one or more additional shell layers onto the 2^{nd} shell layer as a multishell.

According to the present invention, the term “multishell” stands for the stacked shell layers consisting of three or more shell layers.

For example, CdS, CdZnS, CdS/ZnS, ZnS, ZnSe, ZnSe/ZnS or combination of any of these, can be used. Preferably, ZnS, ZnSe, or ZnSe/ZnS can be used as the shell layer.

Ligand Compounds

In some embodiments of the present invention, the outermost surface of the first semiconducting material or the shell layers of the semiconducting light emitting nanoparticle can be partially or fully over coated with one or more of publicly known ligands.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Oleylamine, Dedecyl amine (DDA), Tetradecyl amine (TDA), Hexadecyl amine (HDA), and Octadecyl amine (ODA), Oleylamine (OLA), 1-Octadecene (ODE), thiols such as hexadecane thiol and hexane thiol; mercapto carboxylic acids such as mercapto propionic acid and mercaptoundecanoicacid; carboxylic acids such as oleic acid, stearic acid, myristic acid; acetic acid and a combination of any of these. And also. Polyethylenimine (PEI) also can be used preferably.

Examples of surface ligands have been described in, for example, the laid-open international patent application No. WO 2012/059931A.

In some embodiments of the present invention, an additive selected from one or more members of the group consisting of a solvent, organic light emitting material, inorganic light emitting material, charge transporting material, scattering particle, host material, nanosized plasmonic particle, photo initiator, and a matrix material, can be added in step a) to get a composition.

In a preferred embodiment, said 1^{st} mixture is a composition.

In some embodiments, said additive can be mixed with said semiconducting light emitting nanoparticle or with said 1^{st} organic compound before step a) or after step a) to the 1^{st} mixture obtained in step a) to form a composition.

The details of the additive are described in the section of “Additive for composition” mentioned below.
Composition

In another aspect, the present invention also relates to a composition obtainable or obtained by the process of the present invention.

In another aspect, the present invention further relates to a composition comprising, essentially consisting of, or consisting of, at least

a) one semiconducting light emitting nanoparticle comprising a core, optionally at least one shell layer,
b) a 1^{st} chemical compound, and
c) optionally another compound,
wherein said 1^{st} organic compound is represented by following chemical formula (I),

A(B)ₙC (I)

where A represents a first end group; B is a divalent bond; C is a second end group; n is 0 or 1.

More details of the 1^{st} organic compound is described in the section of “1^{st} organic compound” above.

More details of the semiconducting light emitting nanoparticle is disclosed in the section of “semiconducting light emitting nanoparticle” above.

In a preferred embodiment of the present invention, the compound includes a plurality of the semiconducting light emitting nanoparticles.

In some embodiments of the present invention, the total amount of the 1^{st} chemical compound is in the range from 0.1 wt. % to 90 wt. % based on the total amount of the composition, preferably from 5 wt. % to 70 wt. %, more preferably from 20 wt. % to 50 wt. %.

In some embodiments of the present invention, the total amount of the nanoparticle is in the range from 0.1 wt. % to 100 wt. % based on the total amount of the composition, preferably from 10 wt. % to 50 wt. %, more preferably from 20 wt. % to 30 wt. %.

Additive for Composition

In some embodiments of the present invention, said composition can further contains an additive selected from one or more members of the group consisting of a solvent, organic light emitting material, inorganic light emitting material, charge transporting material, scattering particle, host material, nanosized plasmonic particle, photo initiator, and a matrix material.

For example, said inorganic light emitting material can be selected from one or more member of the group consisting of sulfides, thiogallates, nitrides, oxynitrides, silicate, aluminates, apatites, borates, oxides, phosphates, halophosphates, sulfates, tungstenates, tantalates, vanadates, molybdates, niobates, titanates, germinates, halides-based phosphors, and a combination of any of these.

Such suitable inorganic light emitting materials described above can be well known phosphors including nanosized phosphors, quantum sized materials like mentioned in the phosphor handbook, 2^{nd} edition (CRC Press, 2006), pp. 155-pp. 338 (W. M. Yen, S.Shionoya and H.Yamamoto), WO2011/147517A, WO2012/034625A, and WO2010/095140A.

According to the present invention, as said organic light emitting materials, charge transporting materials, any type of publicly known materials can be used preferably. For example, well known organic fluorescent materials, organic host materials, organic dyes, organic electron transporting materials, organic metal complexes, and organic hole transporting materials.

For examples of scattering particles, small particles of inorganic oxides such as SiO₂, SnO₂, CuO, CoO, Al₂O₃ TiO₂, Fe₂O₃, Y₂O₃, ZnO, MgO; organic particles such as polymerized polystyrene, polymerized PMMA; inorganic hollow oxides such as hollow silica or a combination of any of these; can be used preferably.

Matrix Material

According to the present invention, a wide variety of publicly known transparent polymers suitable for optical devices can be used preferably as a matrix material.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

In a preferred embodiment of the present invention, any type of publicly known transparent polymers, described in for example, WO 2016/134820A can be used.

According to the present invention the term “polymer” means a material having a repeating unit and having the weight average molecular weight (Mw) 1000 g/mol, or more.

The molecular weight MW is determined by means of GPC (=gel permeation chromatography) against an internal polystyrene standard.

In some embodiments of the present invention, the glass transition temperature (Tg) of the transparent polymer is 70° C. or more and 250° C. or less.

Tg is measured based on changes in the heat capacity observed in Differential scanning colorimetry like described in http://pslc.ws/macrog/dsc.htm; Rickey J Seyler, Assignment of the Glass Transition, ASTM publication code number (PCN) 04-012490-50.

For example, as the transparent polymer for the transparent matrix material, poly(meth)acrylates, epoxys, polyurethanes, polysiloxanes, can be used preferably.

In a preferred embodiment of the present invention, the weight average molecular weight (Mw) of the polymer as the transparent matrix material is in the range from 1,000 to 300,000 g/mol, more preferably it is from 10,000 to 250,000 g/mol.

In some embodiments of the present invention, the composition comprises a plural of the semiconducting light emitting nanoparticles and/or a plural of the semiconducting materials.

In some embodiments, the total amount of the chemical compound represented by following chemical formula (I) is in the range from 0.1 wt. % to 90 wt. % based on the total amount of the composition, preferably from 5 wt. % to 70 wt. %, more preferably from 20 wt. % to 50 wt. %.

In some embodiments, the total amount of the nanoparticle is in the range from 0.1 wt. % to 100 wt. % based on the total amount of the composition, preferably from 10 wt. % to 50 wt. %, more preferably from 20 wt. % to 30 wt. %.

Use

In another aspect, the present invention relates to use of the 1^{st} chemical compound represented by chemical formula I) in a composition comprising at least one semiconducting light emitting nanoparticle, or a process for making composition, or a process for making an optical device,

A(B)ₙC (I)

where A represents a first end group; B is a divalent bond; C is a second end group; n is 0 or 1.

In another aspect, the present invention relates to use of the composition according to the present invention, in an electronic device, optical device or in a biomedical device.

Optical Medium

In another aspect, the present invention further relates to an optical medium comprising at least a composition of the present invention.

In another aspect, the present invention also relates to an optical medium comprising at least one semiconducting light emitting nanoparticle, and a 1^{st} chemical compound represented by chemical formula I)

A(B)ₙC (I)

where A represents a first end group; B is a divalent bond; C is a second end group; n is 0 or 1.

In some embodiments of the present invention, the optical medium can be an optical sheet, for example, a color filter, color conversion film, remote phosphor tape, or another film or filter.

According to the present invention, the term “sheet” includes film and/or layer like structured mediums.

In some embodiments of the present invention, the optical medium comprises an anode and a cathode, and at least one organic layer comprising at least a composition of the present invention, preferably said one organic layer is a light emission layer, more preferably the medium further comprises one or more additional layers selected from the group consisting of hole injection layers, hole transporting layers, electron blocking layers, hole blocking layers, electron blocking layers, and electron injection layers.

According to the present invention, any kinds of publicly available inorganic, and/or organic materials for hole injection layers, hole transporting layers, electron blocking layers, light emission layers, hole blocking layers, electron blocking layers, and electron injection layers can be used preferably, like as described in WO 2018/024719 A1, US2016/233444 A2, U.S. Pat. No. 7,754,841 B, WO 2004/037887 and WO 2010/097155.

In a preferable embodiment of the present invention, the optical medium comprises compound including a plurality of the semiconducting light emitting nanoparticles.

Preferably, the anode and the cathode of the optical medium sandwich the organic layer.

More preferably said additional layers are also sandwiched by the anode and the cathode.

In some embodiments of the present invention, the organic layer comprises at least one semiconducting light emitting nanoparticle of the present invention, and a host material, preferably the host material is an organic host material.

In a preferable embodiment of the present invention, the optical medium comprises a composition containing a plurality of the semiconducting light emitting nanoparticles.

Optical Device

In another aspect, the invention further relates to an optical device comprising at least one optical medium of the present invention.

In some embodiments of the present invention, the optical device can be a liquid crystal display device (LCD), Organic Light Emitting Diode (OLED), backlight unit for an optical display, Light Emitting Diode device (LED), Micro Electro Mechanical Systems (here in after “MEMS”), electro wetting display, or an electrophoretic display, a lighting device, and/or a solar cell.

### Technical Effects

The present invention provides one or more of following technical effects; improvement of quantum yield of nanoparticle, preventing or reducing a quantum yield drop under in a diluted composition and/or in a radical rich environment, higher device efficiency, optimizing a surface condition of shell part of nanoparticle, reducing lattice defects of a shell layer of nanoparticle, reducing/preventing formation of dangling bonds of shell layer, better thermal stability, improved oxidation stability, improved stability to a radical substances, improved stability during a long term storage without causing a significant QY drop, better chemical stability, environmentally more friendly and safer fabrication process.

The working examples 1-5 below provide descriptions of the present invention, as well as an in-detail description of their fabrication.

### Working Examples

### Comparative Example 1: A Composition of Quantum Dots in Toluene with Ligands of Dodecanethiol, Stearic Acid, Myristic Acid, and Palmitic Acid

Red InP based Quantum Dots (QDs) with Ligands of Dodecanethiol, stearic acid, myristic acid, and palmitic acid in toluene are prepared like described in U.S. Pat. No. 7,588,828 B.

QDs are then dissolved in dry toluene at a concentration of 0.08 mg/mL and are measured in Hamamatsu Quantaurus for initial Quantum Yield (hereafter initial QY).

Afterwards 100 mg of QDs are dissolved in 2 mL of dried toluene and mixed with 3 mg of photo-initiator Irgacure^{@} TPO and stirred at room temperature under Argon while exposing to a light source with 365 nm for 60 min. The 11 samples are taken. The samples are then diluted to 0.08 mg/mL. And then, Quantum Yield of the 11 samples are measured by Hamamatsu Quantaurus.

The initial QY of each sample is set to 100% by using the following formula.

Normalized initial QY (100%)=initial QY of each sample*α

Normalized QY is calculated based on the following formula.

Normalized QY=(QY*α/Initial QY)*100

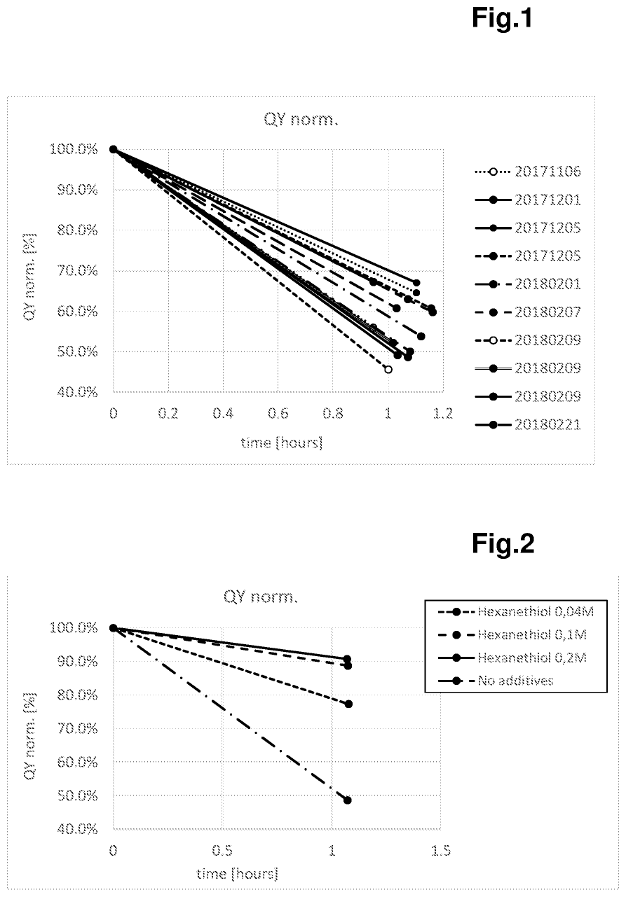

FIG. 1 shows the results of the measurements.

As described in FIG. 1, the average drop of Normalized QY before and after radical tests performed on QDs in Toluene without additives is 40%±7.5%.

### Working Example 1: A Composition of Quantum Dots in Toluene with Additional Chemical Compound Hexanethiol as an Additive of Composition

Red InP based Quantum Dots (QDs) with Ligands of Dodecanethiol, stearic acid, myristic acid, and palmitic acid in toluene are prepared like described in U.S. Pat. No. 7,588,828 B.

Ligand Exchange

QDs are dissolved in dry toluene containing additives (Hexanethiol) in different concentrations (0.004 M, 0.02M, 0.1 M) to make three different samples. QD concentration is set to 0.08 mg/mL for all the three samples and the samples are measured in Hamamatsu Quantaurus for initial QY.

Then it is measured in Hamamatsu Quantaurus for initial Quantum Yield (hereafter initial QY).

Afterwards 100 mg of QDs are dissolved in 2 mL of dried toluene and mixed with 3 mg of photo-initiator Irgacure^{@} TPO and stirred at room temperature under Argon while exposing to a light source with 365 nm for 60 min. The samples are taken. The samples are then diluted to 0.08 mg/mL. And then, Quantum Yield of the samples are measured by Hamamatsu Quantaurus. FIG. 2 shows the results of the measurement.

### Working Example 2: Quantum Dots in Toluene with Additional Chemical Compound 1-Dodecanethiol as an Additive of Composition

A composition of quantum dots in toluene with chemical compound 1-dodecanethiol is prepared in the same manner as described in working example 1 except for that the 0.02 M of 1-dodecanethiol is used instead of hexanethiol.

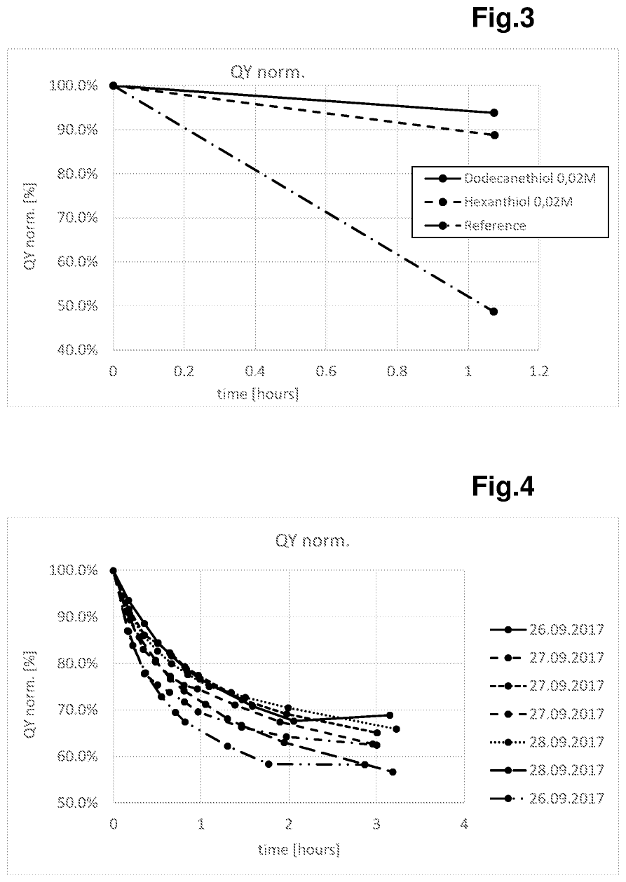

FIG. 3 shows the results of the QY measurements.

### Comparative Example 2: A Composition of Quantum Dots in Toluene with Ligands of Dodecanethiol, Stearic Acid, Myristic Acid, and Palmitic Acid at Lower Concentration

A composition is prepared in the same manner as described in comparative example 1 except for that the concentration of quantum materials in the composition is 0.05 mg/mL. 8 different samples are prepared in the same manner as described in comparative example 2.

FIG. 4 shows the results of the QY measurements of said 7 different samples.

### Working Example 3: A Diluted Composition of Quantum Dots in Toluene with Additional Chemical Compound Hexanethiol as an Additive of Composition

A composition of quantum dots in toluene with chemical compound 1-hexanethiol is prepared in the same manner as described in working example 1 except for that the hexanethiol is used in different amounts to make four different samples in different concentrations of hexanethiol (0.004 M, 0.02M, 0.1M and 0.2M).

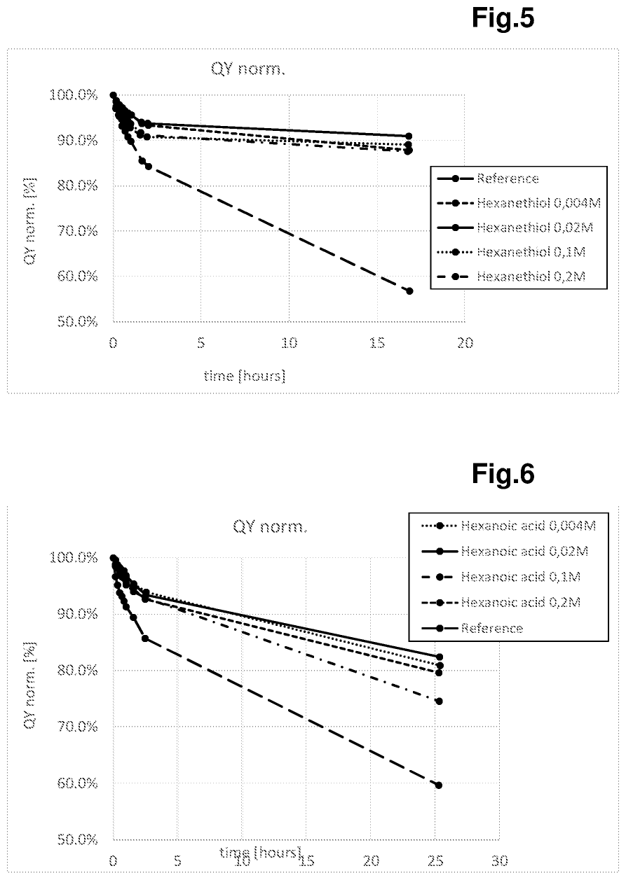

FIG. 5 shows the results of the measurements.

### Working Example 4: A Diluted Composition of Quantum Dots in Toluene with Additional Chemical Compound Hexanoic Acid as an Additive of Composition

A composition of quantum dots in toluene with chemical compound hexanoic acid is prepared in the same manner as described in working example 1 except for that the of hexanoic acid is used in different amounts to make four different samples in different concentrations of hexanoic acid (0.004 M, 0.02M, 0.1M and 0.2M).

FIG. 6 shows the results of the measurements.

### Working Example 5: A Diluted Composition of Quantum Dots in Toluene with Additional Chemical Compound Hexyl Phosphonic Acid (HPA) as an Additive of Composition

A composition of quantum dots in toluene with chemical compound hexyl phosphonic acid (HPA) is prepared in the same manner as described in working example 1 except for that the HPA is used in different amounts to make four different samples in different concentrations of HPA (0.004 M and 0.02M).

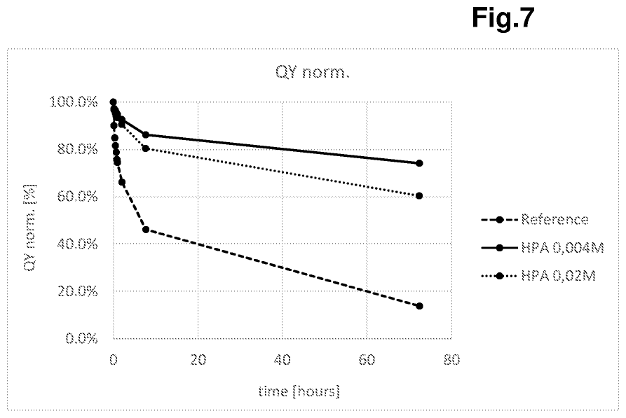

FIG. 7 shows the results of the measurements.

1. A process for preparing a composition comprising;
a) mixing at least a 1^{st} organic compound with a semiconducting light emitting nanoparticle comprising a core, optionally the nanoparticle comprises at least one shell layer, to get a 1^{st} mixture, optionally with another material,
wherein said 1^{st} organic compound is represented by following chemical formula (I),
A(B)ₙC (I)
where A represents a first end group; B is a divalent bond; C is a second end group; n is 0 or 1.

2. A process of claim 1, wherein the amount of the 1^{st} organic compound
is in the range from 0.01 wt. % to 100 wt. % based on the total amount of the inorganic part of the semiconducting light emitting nanoparticle, including the range from 10 wt. % to 50 wt. %, particularly including the range from 20 wt. % to 30 wt. %.

3. A process according to claim 1, wherein the 1^{st} organic compound is represented by following chemical formula (I);
XR¹R²(R³)ₙ
wherein X is selected from P, O, S, or N;
n is 0 in case X is O or S, n is 1 in case X is P or N;
R¹ is selected from one or more members of the group consisting of a hydrogen atom, a linear alkyl group or alkoxyl group having 1 to 40 carbon atoms, including 1 to 25 carbon atoms, particularly including 1 to 15 carbon atoms, a branched alkyl group or alkoxyl group having 3 to 40 carbon atoms, including 3 to 25 carbon atoms, particularly including 3 to 15 carbon atoms, a cycloalkane group having 3 to 40 carbon atoms, including 3 to 25 carbon atoms, particularly including 3 to 15 carbon atoms, an alkenyl group having 2 to 40 carbon atoms, including 2 to 25 carbon atoms, an aryl group having 3 to 40 carbon atoms, including 3 to 25 carbon atoms, a hetero aryl group having 3 to 40 carbon atoms, including 3 to 25 carbon atoms, and an aralkyl group having 4 to 40 carbon atoms, including 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, Cl, Br, I, CN or NO₂, or an aromatic or heteroaromatic ring system having 5 to 60 aromatic ring atoms, which may be substituted by one or more radicals R^{a};
R^{a} is at each occurrence, identically or differently, H, D, or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, C, Br, I; two or more adjacent substituents R^{a} here may also form a mono- or polycyclic, aliphatic, aromatic or heteroaromatic ring system with one another;
R² is selected from one or more members of the group consisting of a hydrogen atom, a linear alkyl group or alkoxyl group having 1 to 40 carbon atoms, including 1 to 25 carbon atoms, particularly including 1 to 15 carbon atoms, a branched alkyl group or alkoxyl group having 3 to 40 carbon atoms, including 3 to 25 carbon atoms, particularly including 3 to 15 carbon atoms, a cycloalkane group having 3 to 40 carbon atoms, including 3 to 25 carbon atoms, particularly including 3 to 15 carbon atoms, an alkenyl group having 2 to 40 carbon atoms, including 2 to 25 carbon atoms, an aryl group having 3 to 40 carbon atoms, including 3 to 25 carbon atoms, a hetero aryl group having 3 to 40 carbon atoms, including 3 to 25 carbon atoms, and an aralkyl group having 4 to 40 carbon atoms, including 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, Cl, Br, I, CN or NO₂, or an aromatic or heteroaromatic ring system having 5 to 60 aromatic ring atoms, which may be substituted by one or more radicals R^{a};
R³ is selected from one or more members of the group consisting of a hydrogen atom, a linear alkyl group or alkoxyl group having 1 to 40 carbon atoms, including 1 to 25 carbon atoms, particularly including 1 to 15 carbon atoms, a branched alkyl group or alkoxyl group having 3 to 40 carbon atoms, including 3 to 25 carbon atoms, particularly including 3 to 15 carbon atoms, a cycloalkane group having 3 to 40 carbon atoms, including 3 to 25 carbon atoms, particularly including 3 to 15 carbon atoms, an alkenyl group having 2 to 40 carbon atoms, including 2 to 25 carbon atoms, an aryl group having 3 to 40 carbon atoms, including 3 to 25 carbon atoms, a hetero aryl group having 3 to 40 carbon atoms, including 3 to 25 carbon atoms, and an aralkyl group having 4 to 40 carbon atoms, including 4 to 25 carbon atoms, which may in each case be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═NR^{a}, SO, SO2, NR^{a}, or CONR^{a} and where one or more H atoms may be replaced by D, F, C, Br, I, CN or NO₂, or an aromatic or heteroaromatic ring system having 5 to 60 aromatic ring atoms, which may be substituted by one or more radicals R^{a};
wherein at least one of R¹, R², R³ is not a hydrogen atom.

4. A process according to claim 1, wherein the 1^{st} organic compound is selected from the group consisting of thiols, selenols, phosphonic acids, carboxylic acids, amines, and phosphines, including a thiol, carboxylic acid, or a phosphonic acid, particularly including hexane-1-thiol, carboxylic acids, 1-dodecanethiol, or hexylphosphonic acid.

5. A process according to claim 1, wherein step a) is carried out with said optional another material, and the amount of the optional another material is in the range from 0.01 wt. % to 100 wt. % based on the total amount of the inorganic part of the semiconducting light emitting nanoparticle, including the range from 0.1 wt. % to 50 wt. %, particularly including the range from 20 wt. % to 30 wt. %.

6. A process according to claim 1, wherein step a) is carried out with said optional another material, and said optional another material is selected from one or more members of the group consisting of photo initiators, thermo initiators, inorganic materials, organic compounds, and solvents.

7. A process according to claim 1, wherein said optional another compound is a solvent selected from inorganic solvents, organic solvents, and a mixture of these, including one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether(PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, and dichlorobenzene, said solvent includes propylene glycol alkyl ether acetates, alkyl acetates, ethylene glycol monoalkyl ethers, propylene glycol, and propylene glycol monoalkyl ethers; the solvent particularly includes one or more members of the group consisting of propylene glycol alkyl ether acetates, such as, propylene glycol monomethyl ether acetate (PGMEA), alkyl acetates such as butyl acetate, ethylene glycol monoalkyl ethers such as ethylene glycol monobutyl ether, propylene glycol or propylene glycol monoalkyl ethers such as methoxypropanol, the solvent more particularly includes propylene glycol alkyl ether acetates.

8. A process according to claim 1, wherein said optional another material is a compound selected from photo initiators, thermo initiators or a mixture of these.

9. A composition obtainable or obtained by the process according to claim 1.

10. A composition comprising at least
a) one semiconducting light emitting nanoparticle comprising a core, optionally at least one shell layer,
b) a 1^{st} chemical compound, and
c) optionally another compound,
wherein said 1^{st} organic compound is represented by following chemical formula (I),
A(B)ₙC (I)
where A represents a first end group; B is a divalent bond; C is a second end group; n is 0 or 1.

11. The composition according to claim 9, wherein the total amount of the 1^{st} chemical compound is in the range from 0.1 wt. % to 90 wt. % based on the total amount of the composition, including from 5 wt. % to 70 wt. %, particularly including from 20 wt. % to 50 wt. %.

12. The composition according to claim 9, wherein the total amount of the nanoparticle is in the range from 0.1 wt. % to 100 wt. % based on the total amount of the composition, including from 10 wt. % to 50 wt. %, particularly including from 20 wt. % to 30 wt. %.

13. A method comprising
a) incorporating the 1^{st} chemical compound represented by chemical formula I) in a composition comprising at least one semiconducting light emitting nanoparticle, or
b) a process for making a composition comprising combining the 1st chemical compound represented by chemical formula I) and a semiconducting light emitting nanoparticle, or
c) a process for making an optical device comprising combining the 1st chemical compound represented by chemical formula I) and a composition comprising at least one semiconducting light emitting nanoparticle,
A(B)ₙC (I)
where A represents a first end group; B is a divalent bond; C is a second end group; n is 0 or 1.

14. A method comprising incorporating a composition according claim 9, in an electronic device, optical device or in a biomedical device.

15. An optical medium comprising at least a composition according to claim 9.

16. An optical medium comprising at least one semiconducting light emitting nanoparticle, and a 1^{st} chemical compound represented by chemical formula I)
A(B)ₙC (I)
where A represents a first end group; B is a divalent bond; C is a second end group; n is 0 or 1.

17. The optical medium of claim 15, comprising an anode and a cathode, and at least one organic layer comprising a composition obtained by
a) mixing at least a 1^{st} organic compound with a semiconducting light emitting nanoparticle comprising a core, optionally the nanoparticle comprises at least one shell layer, to get a 1^{st} mixture, optionally with another material,
wherein said 1^{st} organic compound is represented by following chemical formula (I),
A(B)ₙC (I)
wherein A represents a first end group; B is a divalent bond; C is a second end group; n is 0 or 1,
said one organic layer includes a light emission layer, said optical medium optionally further comprising one or more layers selected from the group consisting of hole injection layers, hole transporting layers, electron blocking layers, hole blocking layers, electron blocking layers, and electron injection layers.

18. The optical medium of claim 16, wherein the organic layer comprises a composition obtained by
a) mixing at least a 1^{st} organic compound with a semiconducting light emitting nanoparticle comprising a core, optionally the nanoparticle comprises at least one shell layer, to get a 1^{st} mixture, optionally with another material,
wherein said 1^{st} organic compound is represented by following chemical formula (I),
A(B)ₙC (I)
wherein A represents a first end group; B is a divalent bond; C is a second end group; n is 0 or 1,
and a host material, the host material including an organic host material.

19. An optical device comprising at least one optical medium according to claim 15.
